(19) United States
(12) Patent Application Publication
(10) Pub. No.: US 2025/0275448 A1
(43) Pub. Date: Aug. 28, 2025

(54) Mitigation of Diffraction Artifacts in Polarizer-Free Displays

(71) Applicant: Apple Inc., Cupertino, CA (US)

(72) Inventors: Hao Chen, Santa Clara, CA (US); Sukru Ekin Kocabas, Santa Clara, CA (US); Xiao Li, Santa Clara, CA (US); Yujia Zhai, San Jose, CA (US); Yue Qu, Redwood City, CA (US); Shih-Chyuan Fan Jiang, San Jose, CA (US); Young Cheol Yang, Sunnyvale, CA (US); ByoungSuk Kim, Palo Alto, CA (US); Mingxia Gu, Campbell, CA (US); Zhibing Ge, Sunnyvale, CA (US); Jun Qi, San Jose, CA (US)

(21) Appl. No.: 18/890,457

(22) Filed: Sep. 19, 2024

Related U.S. Application Data
(60) Provisional application No. 63/558,832, filed on Feb. 28, 2024.

(51) Int. Cl. H10K 59/80; H10K 59/122; H10K 59/38

(52) U.S. Cl. CPC H10K 59/8792; H10K 59/122; H10K 59/38; H10K 59/80515; H10K 59/877

(57) ABSTRACT

A display may include an array of pixels such as light-emitting diode pixels. The circular polarizer may be omitted from the display to increase efficiency. A polarizer-free display may use other non-polarizer techniques to mitigate reflections of ambient light and mitigate associated diffraction artifacts. The polarizer-free display may include a black matrix, color filter element, or pixel definition layer with tapered surfaces to make changes in reflectance associated with the subpixels more gradual. Instead or in addition, a subpixel may have a footprint with one or more protrusions. Instead or in addition, different pixels may have subpixels with different elliptical footprints and/or different footprints with protrusions. Instead or in addition, the polarizer-free display may include color filter elements with concave upper surfaces. Instead or in addition, the polarizer-free display may include subpixels with varying anode heights.

This application claims the benefit of U.S. provisional patent application No. 63/558,832, filed Feb. 28, 2024, which is hereby incorporated by reference herein in its entirety.

### BACKGROUND

Electronic devices often include displays. For example, cellular telephones and portable computers include displays for presenting information to users. An electronic device may have an organic light-emitting diode display based on organic-light-emitting diode pixels or a liquid crystal display based on liquid crystal pixels. Displays sometimes include a circular polarizer to mitigate reflections. However, the circular polarizer may decrease the efficiency of the display.

It is within this context that the embodiments herein arise.

### SUMMARY

A display that includes a substrate, an array of light-emitting diodes on the substrate, a black matrix that is formed over the array of light-emitting diodes and that defines a plurality of openings, and a plurality of color filter elements. Each one of the plurality of color filer elements may be formed in a respective opening of the plurality of openings and at least one of the black matrix and the plurality of color filter elements may have tapered surfaces to mitigate diffraction artifacts.

A display may include a substrate, an array of light-emitting diodes on the substrate, a black matrix that defines openings for the light-emitting diodes, and a plurality of color filter elements. Each one of the plurality of color filer elements may formed in a respective opening of the openings and the openings may have at least four unique footprints.

A display may include a substrate, an array of light-emitting diodes on the substrate, a black matrix that is formed over the array of light-emitting diodes and that defines a plurality of openings, and a plurality of color filter elements. Each one of the plurality of color filer elements may be formed in a respective opening of the plurality of openings and may have a concave upper surface.

A display may include a substrate having a surface, an array of light-emitting diodes on the substrate, a black matrix that is formed over the array of light-emitting diodes and that defines a plurality of openings, and a plurality of color filter elements. Each light-emitting diode may include an anode, each anode may have a displacement relative to the surface, there may be at least four unique displacements in the array of light-emitting diodes, and each one of the plurality of color filer elements may be formed in a respective opening of the plurality of openings.

### BRIEF DESCRIPTION OF THE DRAWINGS

FIG. 1 is a schematic diagram of an illustrative electronic device having a display in accordance with some embodiments.

FIG. 2 is a schematic diagram of an illustrative display in accordance with some embodiments.

FIG. 3A is a cross-sectional side view of an illustrative display with a circular polarizer in accordance with some embodiments.

FIG. 3B is a cross-sectional side view of an illustrative display without a circular polarizer in accordance with some embodiments.

FIG. 4 is a cross-sectional side view of an illustrative polarizer-free display with color filter elements in accordance with some embodiments.

FIG. 5A is an illustrative reflectance profile showing the reflectance of red light across the footprint of a red subpixel with a red color filter element in accordance with some embodiments.

FIG. 5B is an illustrative reflectance profile showing the reflectance of red light across the footprint of a red subpixel with a red color filter element and a tapered component in accordance with some embodiments.

FIG. 6 is a cross-sectional side view of an illustrative polarizer-free display with color filter elements and black matrix having tapered surfaces in accordance with some embodiments.

FIG. 7 is a cross-sectional side view of an illustrative polarizer-free display with color filter elements having tapered surfaces in accordance with some embodiments.

FIG. 8 is a cross-sectional side view of an illustrative polarizer-free display with color filter elements and a pixel definition layer having tapered surfaces in accordance with some embodiments.

FIGS. 9A-9C are side views of illustrative tapered surfaces with different shapes in accordance with some embodiments.

FIG. 10 is a top view of an illustrative pixel with subpixels having circular footprints and ring-shaped tapered surfaces in accordance with some embodiments.

FIG. 11 is a top view of an illustrative subpixel with a footprint that has protrusions in accordance with some embodiments.

FIGS. 12A-12D are top views of illustrative protrusions with different shapes in accordance with some embodiments.

FIG. 13 is a top view of an illustrative display with pixels having subpixels with different footprints with protrusions in accordance with some embodiments.

FIG. 14 is a top view of an illustrative display with pixels having subpixels with different elliptical footprints in accordance with some embodiments.

FIG. 15 is a top view of an illustrative display with repeating unit cells of pixels that are rotated relative to one another in accordance with some embodiments.

FIG. 16 is a top view of an illustrative display with repeating unit cells of pixels that have varying spatial frequency in accordance with some embodiments.

FIG. 17 is a cross-sectional side view of an illustrative polarizer-free display with color filter elements having concave upper surfaces in accordance with some embodiments.

FIG. 18 is a cross-sectional side view of an illustrative polarizer-free display with varying anode heights in accordance with some embodiments.

FIG. 19 is a cross-sectional side view of an illustrative polarizer-free display with diffuser rings in accordance with some embodiments.

### DETAILED DESCRIPTION

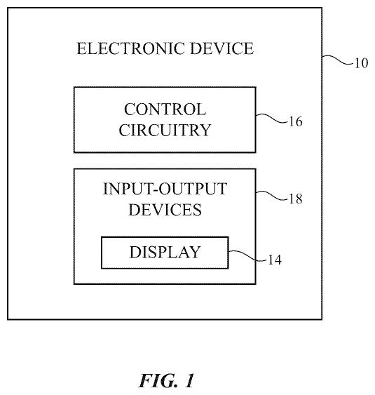

An illustrative electronic device of the type that may be provided with a display is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, an augmented reality (AR) headset and/or virtual reality (VR) headset, a device embedded in eyeglasses or other equipment worn on a user's head, or other wearable or miniature device, a display, a computer display that contains an embedded computer, a computer display that does not contain an embedded computer, a gaming device, a navigation device, an embedded system such as a system in which electronic equipment with a display is mounted in a kiosk or automobile, or other electronic equipment.

As shown in FIG. 1, electronic device 10 may have control circuitry 16. Control circuitry 16 may include storage and processing circuitry for supporting the operation of device 10. The storage and processing circuitry may include storage such as hard disk drive storage, nonvolatile memory (e.g., flash memory or other electrically-programmable-read-only memory configured to form a solid state drive), volatile memory (e.g., static or dynamic random-access-memory), etc. Processing circuitry in control circuitry 16 may be used to control the operation of device 10. The processing circuitry may be based on one or more microprocessors, microcontrollers, digital signal processors, baseband processors, power management units, audio chips, application specific integrated circuits, etc.

Input-output circuitry in device 10 such as input-output devices 18 may be used to allow data to be supplied to device 10 and to allow data to be provided from device 10 to external devices. Input-output devices 18 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input-output devices 18 and may receive status information and other output from device 10 using the output resources of input-output devices 18.

Input-output devices 18 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements.

Control circuitry 16 may be used to run software on device 10 such as operating system code and applications. During operation of device 10, the software running on control circuitry 16 may display images on display 14.

Display 14 may be an organic light-emitting diode display, a display formed from an array of discrete light-emitting diodes each formed from a crystalline semiconductor die, or any other suitable type of display. Configurations in which the pixels of display 14 include light-emitting diodes are sometimes described herein as an example. This is, however, merely illustrative. Any suitable type of display may be used for device 10, if desired (e.g., a liquid crystal display).

In some cases, electronic device 10 may be a wristwatch device. Display 14 of the wristwatch device may be positioned in a housing. A wristwatch strap may be coupled to the housing.

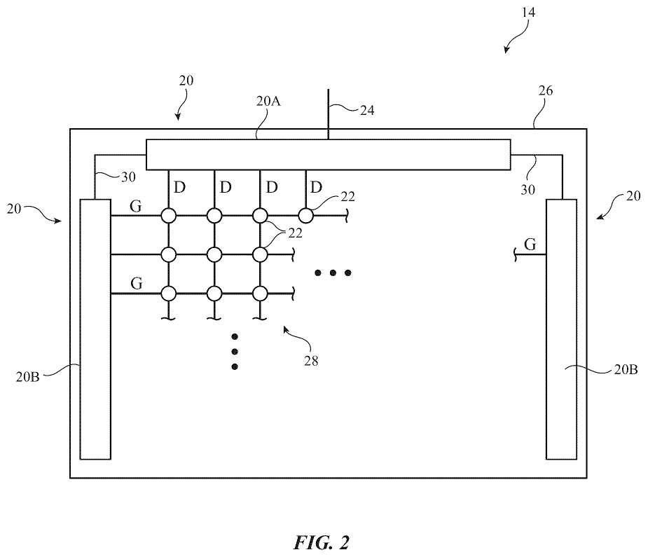

FIG. 2 is a diagram of an illustrative display. As shown in FIG. 2, display 14 may include layers such as substrate layer 26. Substrate layers such as layer 26 may be formed from rectangular planar layers of material or layers of material with other shapes (e.g., circular shapes or other shapes with one or more curved and/or straight edges). The substrate layers of display 14 may include glass layers, polymer layers, composite films that include polymer and inorganic materials, metallic foils, etc.

Display 14 may have an array of pixels 22 for displaying images for a user such as subpixel array 28. Pixels 22 in array 28 may be arranged in rows and columns. The edges of array 28 (sometimes referred to as active area 28) may be straight or curved (i.e., each row of pixels 22 and/or each column of pixels 22 in array 28 may have the same length or may have a different length). There may be any suitable number of rows and columns in array 28 (e.g., ten or more, one hundred or more, or one thousand or more, etc.). Each pixel in display 14 may include subpixels of different colors. As an example, display 14 may include red subpixels, green subpixels, and blue subpixels. If desired, a backlight unit may provide backlight illumination for display 14.

Display driver circuitry 20 may be used to control the operation of pixels 22. Display driver circuitry 20 may be formed from integrated circuits, thin-film transistor circuits, and/or other suitable circuitry. Illustrative display driver circuitry 20 of FIG. 2 includes display driver circuitry 20A and additional display driver circuitry such as gate driver circuitry 20B. Gate driver circuitry 20B may be formed along one or more edges of display 14. For example, gate driver circuitry 20B may be arranged along the left and right sides of display 14 in an inactive area of the display as shown in FIG. 2. Gate driver circuitry 20B may include gate drivers and emission drivers.

As shown in FIG. 2, display driver circuitry 20A (e.g., one or more display driver integrated circuits, thin-film transistor circuitry, etc.) may contain communications circuitry for communicating with system control circuitry over signal path 24. Path 24 may be formed from traces on a flexible printed circuit or other cable. The control circuitry may be located on one or more printed circuits in electronic device 10. During operation, the control circuitry (e.g., control circuitry 16 of FIG. 1) may supply circuitry such as a display driver integrated circuit in circuitry 20 with image data for images to be displayed on display 14. Display driver circuitry 20A of FIG. 2 is located at the top of display 14. This is merely illustrative. Display driver circuitry 20A may be located at both the top and bottom of display 14 or in other portions of device 10.

To display the images on pixels 22, display driver circuitry 20A may supply corresponding image data to data lines D (e.g., vertical signal lines) while issuing control signals to supporting display driver circuitry such as gate driver circuitry 20B over signal paths 30. With the illustrative arrangement of FIG. 2, data lines D run vertically through display 14 and are associated with respective columns of pixels 22. During compensation operations, column driver circuitry 20 may use paths such as data lines D to supply a reference voltage.

Gate driver circuitry 20B (sometimes referred to as gate line driver circuitry or horizontal control signal circuitry) may be implemented using one or more integrated circuits and/or may be implemented using thin-film transistor circuitry on substrate 26. Horizontal control lines G (sometimes referred to as gate lines, scan lines, emission control lines, etc.) run horizontally through display 14. Each gate line G is associated with a respective row of pixels 22. If desired, there may be multiple horizontal control lines such as gate lines G associated with each row of pixels. Individually controlled and/or global signal paths in display 14 may also be used to distribute other signals (e.g., power supply signals, etc.). The number of horizontal signal lines in each row may be determined by the number of transistors in the display pixels 22 that are being controlled independently by the horizontal signal lines. Display pixels of different configurations may be operated by different numbers of control lines, data lines, power supply lines, etc.

Gate driver circuitry 20B may assert control signals on the gate lines G in display 14. For example, gate driver circuitry 20B may receive clock signals and other control signals from circuitry 20A on paths 30 and may, in response to the received signals, assert a gate line signal on gate lines G in sequence, starting with the gate line signal G in the first row of pixels 22 in array 28. As each gate line is asserted, data from data lines D may be loaded into a corresponding row of pixels. In this way, control circuitry such as display driver circuitry 20A and 20B may provide pixels 22 with signals that direct pixels 22 to display a desired image on display 14. Each pixel may have multiple subpixels that have a light-emitting diode and circuitry (e.g., thin-film circuitry on substrate 26) that respond to the control and data signals from display driver circuitry 20.

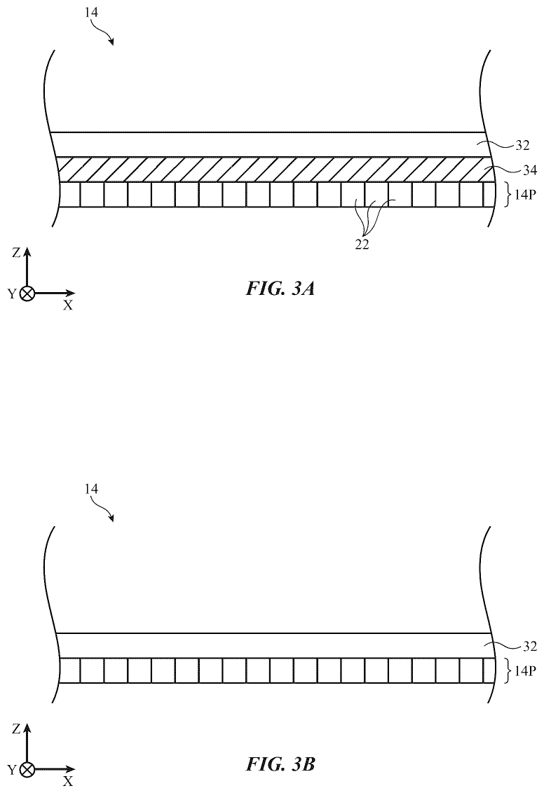

Some displays may include a circular polarizer to mitigate reflections of ambient light. As shown in FIG. 3A, display 14 includes a display panel 14P with an array of pixels 22. Display panel 14P may be an organic light-emitting diode display panel, a display panel formed from an array of discrete light-emitting diodes each formed from a crystalline semiconductor die, a liquid crystal display panel, or any other suitable type of display. The display panel 14P is covered by a display cover layer 32. Display cover layer 32 may be a transparent material that forms an outer surface of the display (and device 10). The display cover layer 32 may protect the underlying display panel from damage during operation of the device. The display cover layer 32 may be formed from plastic, glass, sapphire, or any other desired material.

In FIG. 3A, a circular polarizer 34 is interposed between the display panel 14P and the display cover layer 32. Circular polarizer 34 may include a linear polarizer and a quarter wave plate. The circular polarizer serves to mitigate undesired reflections of ambient light off of display panel 14P. When ambient light passes in the negative Z-direction through display cover layer 32 and circular polarizer 34, the light becomes circularly polarized. The light may subsequently reflect off of reflective layers of display panel 14P (e.g., anodes for the pixels 22 in display panel 14P). The reflected light (now traveling in the positive Z-direction) has the opposite circular polarization and is subsequently absorbed by the circular polarizer 34. The circular polarizer 34 therefore effectively prevents ambient light reflections off of display panel 14P, improving contrast in display 14.

Although effective at mitigating ambient light reflections, circular polarizer 34 reduces the efficiency of display 14. The display light emitted by pixels 22 passes through circular polarizer 34 when exiting the display. This reduces the intensity of the display light exiting display 14.

To improve the efficiency of the display, circular polarizer 34 may be omitted from the display. FIG. 3B is a cross-sectional side view of a display of this type. As shown, display cover layer 32 is formed over display panel 14P without an intervening circular polarizer. This type of display may sometimes be referred to as a polarizer-free display, a circular-polarizer-free display, a polarizer-free OLED display, circular-polarizer-free OLED display etc.

Omitting the circular polarizer in display 14 increases the efficiency of the display. Additionally, omitting the circular polarizer in display 14 may help align the neutral stress plane of the display with sensitive components in display panel 14P (e.g., the thin-film transistor circuitry in the display panel). This makes the display more robust to bending and folding. Yet another advantage of omitting the circular polarizer is improved efficiency/performance for input-output components that operate through the display. For example, an optical sensor may sense light that passes through the display. Omitting the circular polarizer increases the signal-to-noise ratio for the optical sensor.

The polarizer-free display may use other techniques to mitigate artifacts caused by reflections of ambient light and preserve a high contrast for the display.

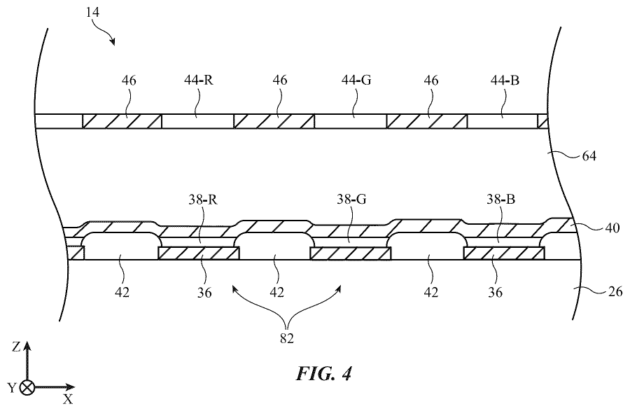

FIG. 4 is a side view of an illustrative polarizer-free display. As shown in FIG. 4, the display includes organic light-emitting diode subpixels 82 on substrate 26. Each OLED subpixel 82 includes an electrode (anode) 36, OLED layers 38, and a common electrode (cathode) 40. The OLED layers 38 may include OLED layers such as a hole injection layer, a hole transport layer, an emissive layer, an electron transport layer, an electronic injection layer, an electron blocking layer, a charge generation layer, and/or a hole blocking layer. Each subpixel may include a single diode or a tandem diode. A common cathode 40 is formed over the array of pixels. The cathode may be formed as a blanket layer across the entire array and serves as the cathode electrode for each subpixel in the display. The OLED layers 38 are interposed between the cathode 40 and respective anodes 36. Each subpixel may have an emissive layer of a selected color (e.g., red, green, or blue) as one of its OLED layers 38. As shown in FIG. 4, a first subpixel includes red OLED layers 38-R that are configured to emit red light, a second subpixel includes green OLED layers 38-G that are configured to emit green light, and a third subpixel includes blue OLED layers 38-B that are configured to emit blue light.

Display 14 also includes a pixel definition layer 42. The pixel definition layer 42 may be formed from a dielectric material and may be used to define light-emitting apertures for each subpixel. The OLED layers 38 and corresponding anodes 36 are formed in the apertures defined by the pixel definition layer 42. Pixel definition layer 42 may optionally be opaque.

As shown in FIG. 4, display 14 also includes color filter elements 44 that are formed within openings in a grid of black matrix 46 (sometimes referred to as black masking layer 46, opaque masking layer 46, etc.). Each color filter element 44 may overlap a respective subpixel 82 that emits light at a given color (wavelength). Each color filter element 44 may transmit light at the given wavelength for its overlapped subpixel while blocking light for other wavelengths. For example, each red OLED subpixel 82 is overlapped by a red color filter 44-R that transmits red light while blocking blue light and green light. Each green OLED subpixel 82 is overlapped by a green color filter 44-G that transmits green light while blocking blue light and red light. Each blue OLED subpixel 82 is overlapped by a blue color filter 44-B that transmits blue light while blocking red light and green light.

The color filter elements 44 allow light from the display subpixels to pass through to the viewer. Therefore, the display performance is not negatively impacted by the color filter elements. Simultaneously, the color filter elements 44 block much of the ambient light from being reflected. Each blue color filter element blocks red and green ambient light from being reflected, each red color filter element blocks blue and green ambient light from being reflected, and each green color filter element blocks red and blue ambient light from being reflected. Each color filter element may therefore block approximately ⅔ of incident ambient light.

Black matrix 46 may be formed from any desired material that absorbs light. Black matrix 46 may reflect less than 20% of incident light, less than 10% of incident light, less than 5% of incident light, less than 3% of incident light, less than 1% of incident light, etc. Black matrix 46 may transmit less than 20% of incident light, less than 10% of incident light, less than 5% of incident light, less than 3% of incident light, less than 1% of incident light, etc. Black matrix 46 may absorb more than 50% of incident light, more than 75% of incident light, more than 90% of incident light, more than 95% of incident light, etc. Black matrix 46 blocks ambient light from reflecting off the display.

In FIG. 4, one or more planarization layers 64 may be formed between cathode 40 and color filter elements 44 and black matrix 46. The one or more planarization layers 64 has first and second opposing sides. Cathode 40 (and the OLED subpixels 82) is formed on the first side whereas color filter elements 44 and black matrix 46 are formed on the second side. The one or more planarization layers 64 may be formed from, for example, organic dielectric material that is deposited using inkjet printing (IJP). The planarization layer(s) 64 may therefore sometime be referred to as dielectric layer(s) 64, IJP layer(s) 64, organic layer(s) 64, etc. Color filter elements 44 and black matrix 46 may be formed in direct contact with an upper surface of IJP layer(s) 64.

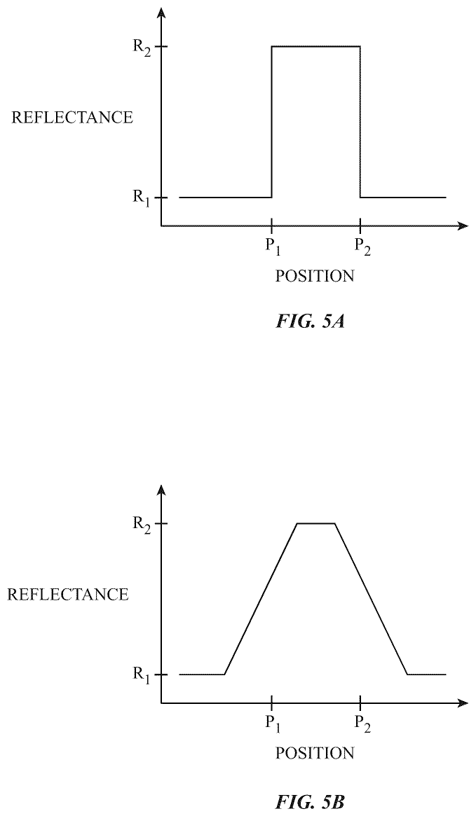

The display of FIG. 4 may have diffraction artifacts associated with reflections of ambient light in display 14. The diffraction artifacts may be at least partially caused by the step change in reflectivity across the display. FIG. 5A shows the reflectance of red light across the footprint of a red subpixel with a red color filter element. The red light is not blocked by the red color filter element. Accordingly, ambient red light passes through the red color filter element, reflects off an underlying reflective layer (e.g., anode 36), and passes through the red color filter element towards the viewer. In the arrangement of FIG. 4, the black matrix 46 has vertical edges. Accordingly, as shown by the reflectance profile in FIG. 5A, the reflectance has a step change between minimum reflectance R₁ in areas overlapped by the black matrix and maximum reflectance R₂ in areas not overlapped by the black matrix (e.g., between positions P₁ and P₂). This type of reflection profile may be associated with strong diffraction artifacts.

To mitigate diffraction artifacts, one or more components within display 14 may have a varying thickness (and corresponding tapered surface) to cause the reflectance profile to gradually change between R₁ and R₂. FIG. 5B shows the reflectance of red light across the footprint of a red subpixel with a red color filter element and a tapered component. As shown by the reflectance profile in FIG. 5B, similar to as in FIG. 5A, has an associated minimum reflectance R₁ in an area overlapped by the black matrix and maximum reflectance R₂ in an area not overlapped by the black matrix. Between R₁ and R₂, the reflectance may change gradually. This gradual change in the reflectance profile may mitigate diffraction artifacts in ambient light reflected off display 14.

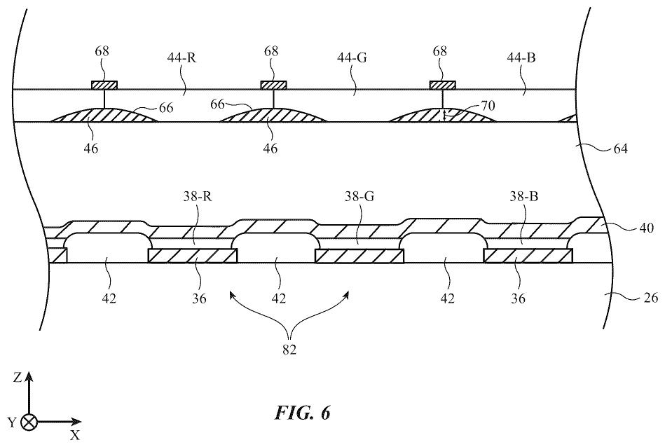

FIG. 6 is a side view of an illustrative display with black matrix having a tapered surface. As shown in FIG. 6, black matrix layer 46 has tapered surfaces 66 where the thickness of the black matrix layer 46 gradually changes. In particular, the black matrix may have a maximum thickness 70 in a portion of the black matrix layer (e.g., a portion that is equidistant from the closest color filter elements and/or that is aligned with an interface between adjacent color filter elements). The thickness of the black matrix may gradually decrease from maximum thickness 70 to a thickness of 0 at a point that overlaps a respective subpixel 82. The thickness of the black matrix layer therefore decreases with decreasing separation from a center of a respective subpixel 82. The thickness of the black matrix layer may decrease continuously and monotonically across tapered surface 66.

The transmittance of light through the black matrix layer may increase with decreasing thickness of the black matrix. Through the maximum thickness of the black matrix layer, the transmittance through the black matrix layer (e.g., the minimum transmittance) may be less than 20%, less than 10%, less than 5%, less than 3%, etc. At the edge of the black matrix layer where the thickness of the black matrix layer is 0, the transmittance through the black matrix layer (e.g., the maximum transmittance) may be 100% (since there is no black matrix material to block the light). At an intermediate point between the maximum thickness portion and the edge (e.g., where the thickness is greater than 0 but less than the maximum thickness), the transmittance through the black matrix layer may be 50%. The transmittance may change gradually between the minimum and maximum values as the thickness gradually decreases due to tapered surface 66. This type of transmittance profile may cause a subpixel to have the reflectance profile of FIG. 5B, desirably mitigating diffraction artifacts associated with reflections of ambient light.

FIG. 6 shows how an additional black matrix layer 68 may be formed on an upper surface of color filter elements 44. The additional black matrix layer 68 may overlap an interface between adjacent color filter elements 44. Black matrix layer 68 may optionally have tapered surfaces in a similar fashion to black matrix layer 46 in FIG. 6. Alternatively, black matrix layer 68 may have a uniform thickness but a smaller footprint than the corresponding overlapping portions of block matrix layer 46.

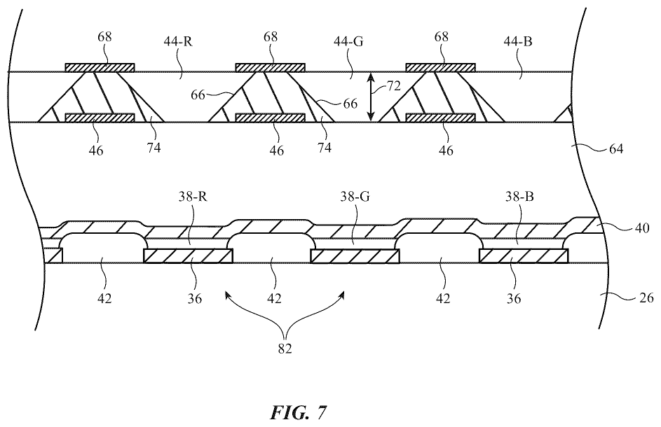

Instead or in addition to black matrix layer 46 having tapered surfaces, one or more colored filter element 44 in display 14 may have tapered surfaces to mitigate diffraction artifacts. FIG. 7 is a side view of a display with color filter elements having tapered surfaces. As shown, each color filter element has tapered side surfaces 66. The color filter element has a maximum thickness 72 in a center portion of the color filter element. The thickness of the color filter element may gradually decrease from maximum thickness 72 to a thickness of 0 at a point overlapped by black matrix layers 46 and/or 68. The thickness of the color filter element therefore decreases with increasing separation from a center of a respective subpixel 82. The thickness of the color filter element may decrease continuously and monotonically across tapered surface 66.

Between adjacent color filter elements, a filler material 74 may be formed. In one example, the filler material may be formed from a color filtering material. For example, filler material 74 may be formed from the blue color filtering material used to form blue color filter element 44-B, may be formed from the green color filtering material used to form green color filter element 44-G, or may be formed from the red color filtering material used to form red color filter element 44-R. Different filler material may optionally be used between adjacent subpixels of different colors. For example, filler material 74 between a red subpixel and a green subpixel may be formed from blue color filtering material whereas filler material 74 between a green subpixel and a blue subpixel may be formed from red color filtering material. This example is merely illustrative. In another possible arrangement, filler material 74 may be formed from blue color filtering material between each pair of adjacent subpixels (e.g., between blue and green subpixels, between blue and red subpixels, and between green and red subpixels). The human eye may tend to be less sensitive to diffraction artifacts at blue light wavelengths than at red and green light wavelengths. Using a blue filler material between each adjacent pair of subpixels may therefore optimize the mitigation of diffraction artifacts with the cost and complexity of manufacturing.

Consider an example where blue color filtering material 74 is formed between red color filter element 44-R and green color filter element 44-G. The transmittance of red light through the color filter element 44-R may decrease with decreasing thickness of the color filter element. Through the maximum thickness 72 of the color filter element, the transmittance of red light (e.g., the maximum transmittance) may be greater than 90%, greater than 95%, etc. At the edge of the color filter element where the thickness of the color filter element is 0, the red light passes exclusively through the blue color filtering material and the transmittance of red light (e.g., the minimum transmittance) is therefore less than 20%, less than 10%, less than 5%, less than 3%, etc. At an intermediate point between the maximum thickness portion and the edge (e.g., where the thickness is greater than 0 but less than the maximum thickness), the transmittance of red light may be 50%. The transmittance may change gradually from the maximum value to the minimum value as the thickness of the color filter element gradually decreases due to tapered surface 66. This type of transmittance profile may cause a subpixel to have the reflectance profile of FIG. 5B, desirably mitigating diffraction artifacts associated with reflections of ambient light.

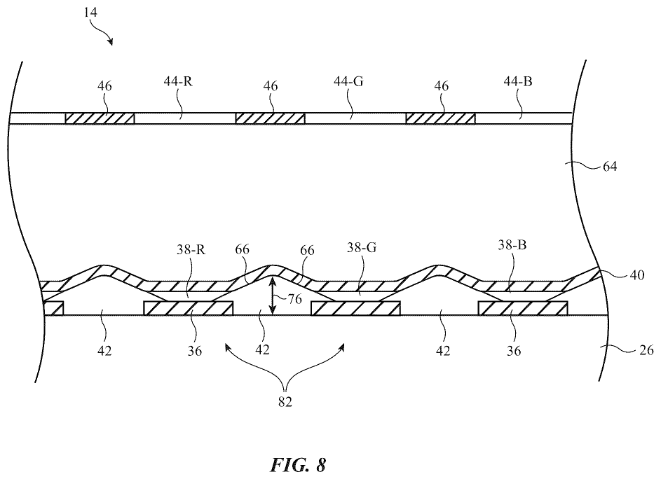

FIG. 8 is a side view of an illustrative display with an opaque pixel definition layer having a tapered surface. As shown in FIG. 8, pixel definition layer 42 has tapered surfaces 66 where the thickness of the pixel definition layer gradually changes. Pixel definition layer 42 may be formed from an opaque material (e.g., a black material). The pixel definition layer 42 may have a maximum thickness 76 in a portion of the pixel definition layer between adjacent subpixels (e.g., at a point equidistance between the two closest subpixels). The thickness of the pixel definition layer may gradually decrease from maximum thickness 76 to a thickness of 0 at a point that overlaps a respective subpixel 82. The thickness of the pixel definition layer therefore decreases with decreasing separation from a center of a respective subpixel 82. The thickness of the pixel definition layer may decrease continuously and monotonically across tapered surface 66.

The transmittance of light through the pixel definition layer may increase with decreasing thickness of the pixel definition layer. Through the maximum thickness of the pixel definition layer, the transmittance through the pixel definition layer (e.g., the minimum transmittance) may be less than 40%, less than 20%, less than 10%, less than 5%, less than 3%, etc. At the edge of the pixel definition layer where the thickness of the pixel definition layer is 0, the transmittance through the pixel definition layer (e.g., the maximum transmittance) may be 100% (since there is no pixel definition layer material to block the light). At an intermediate point between the maximum thickness portion and the edge (e.g., where the thickness is greater than 0 but less than the maximum thickness), the transmittance through the pixel definition layer may be 50%. The transmittance may change gradually between the minimum and maximum values as the thickness gradually decreases due to tapered surface 66. This type of transmittance profile may cause a subpixel to have the reflectance profile of FIG. 5B, desirably mitigating diffraction artifacts associated with reflections of ambient light.

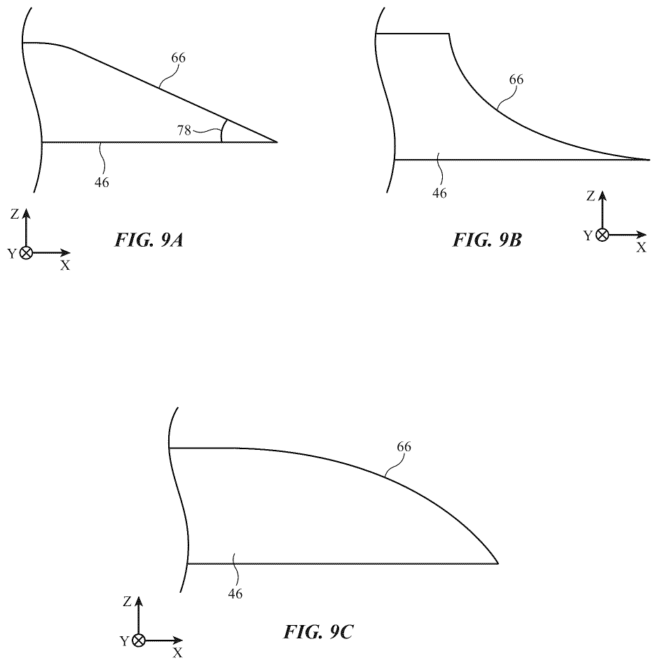

FIGS. 9A-9C are side views of components with different shapes for sloped surfaces 66. FIG. 9A shows an example where tapered surface 66 is planar and at an angle 78 relative to a lower surface that is parallel to the XY-plane (where light is emitted in the positive Z-direction). Angle 78 may be greater than 5 degrees, greater than 25 degrees, greater than 45 degrees, greater than 75 degrees, less than 85 degrees, less than 65 degrees, less than 45 degrees, less than 25 degrees, between 30 degrees and 60 degrees, etc.

FIG. 9B shows an example where tapered surface 66 has concave curvature. The rate of decrease in thickness in the component is initially at a maximum and then becomes smaller over time (while moving in the positive X-direction). The opposite arrangement may instead be used. FIG. 9C shows an example where tapered surface 66 has convex curvature. The rate of decrease in thickness in the component is initially at a minimum and then becomes greater over time (while moving in the positive X-direction). In each one of FIGS. 9A-9C, the tapered surface is shaped such that the thickness of the component decreases continuously and monotonically.

The example in FIGS. 9A-9C of the component with the tapered surface being black matrix 46 is merely illustrative. It should be understood that any component with a tapered surface (e.g., black matrix as in FIG. 6, a color filter element as in FIG. 7, and/or a pixel definition layer as in FIG. 8) may have any of the tapered surface shapes shown in FIGS. 9A-9C.

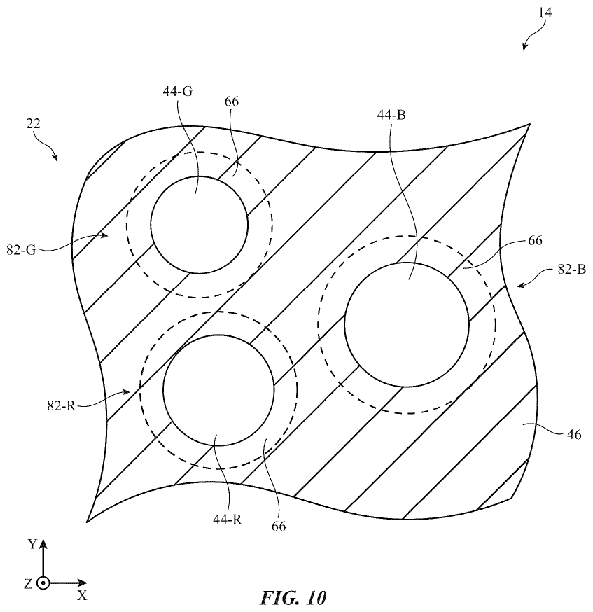

FIG. 10 is a top view of an illustrative pixel with a green subpixel 82-G, a red subpixel 82-R, and a blue subpixel 82-B. Each pixel has a respective color filter element. Green subpixel 82-G has a green color filter element 44-G in a black matrix opening with a footprint that corresponds to the light-emitting area for that subpixel, blue subpixel 82-B has a blue color filter element 44-B in a black matrix opening with a footprint that corresponds to the light-emitting area for that subpixel, and red subpixel 82-R has a red color filter element 44-R in a black matrix opening with a footprint that corresponds to the light-emitting area for that subpixel. In FIG. 10, each color filter element (and each light-emitting area) has a circular footprint. In FIG. 10, the black matrix 46 defines openings with circular footprints that overlap the color filter elements. As shown in FIG. 10, a tapered surface 66 may surround each opening in the black matrix. The dashed lines in FIG. 10 indicate the start of the tapered surface 66 associated with each opening.

Tapered surfaces 66 in black matrix 46 therefore have a ring shape that laterally surrounds a respective subpixel. Tapered surfaces in color filter elements 44 or pixel definition layer 42 may have the same footprint(s) shown in FIG. 10.

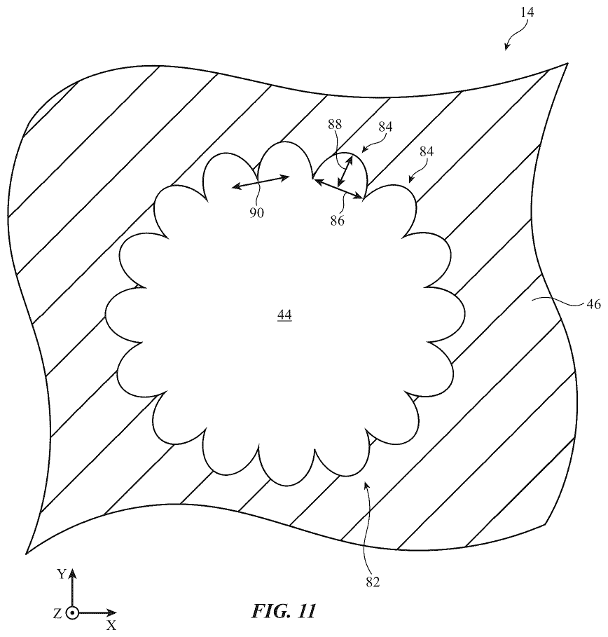

The example of each subpixel having a circular footprint in FIG. 10 is merely illustrative. To mitigate diffraction artifacts, one or more subpixels in the display may have a footprint with one or more protrusions. FIG. 11 is a top view of an illustrative subpixel with a footprint having protrusions. As shown, the footprint of subpixel 82 has a plurality of protrusions 84 around the circumference of the subpixel. Each protrusion has a height 88 and width 86. Adjacent protrusions may be separated by a center-to-center pitch 90. The protrusions may extend from a base shape for the footprint (e.g., a circle in FIG. 11).

In general, any desired magnitudes may be used for width 86, height 88, and pitch 90 (e.g., less than 20 microns, less than 10 microns, less than 5 microns, less than 3 microns, less than 1 micron, greater than 1 micron, greater than 3 microns, greater than 5 microns, greater than 10 microns, etc.). Incorporating one or more protrusions into the footprint of the light-emitting area of a subpixel may mitigate diffraction artifacts associated with that subpixel.

FIG. 11 shows an example where there are 16 protrusions evenly spaced around the circumference of the subpixel. This example is merely illustrative. In general, the subpixel's footprint may include any desired number of protrusions (e.g., less than 20, less than 15, less than 12, less than 8, less than 5, more than 20, more than 15, more than 12, more than 8, more than 5). The protrusions may optionally have irregular center-to-center pitch around the circumference of the subpixel.

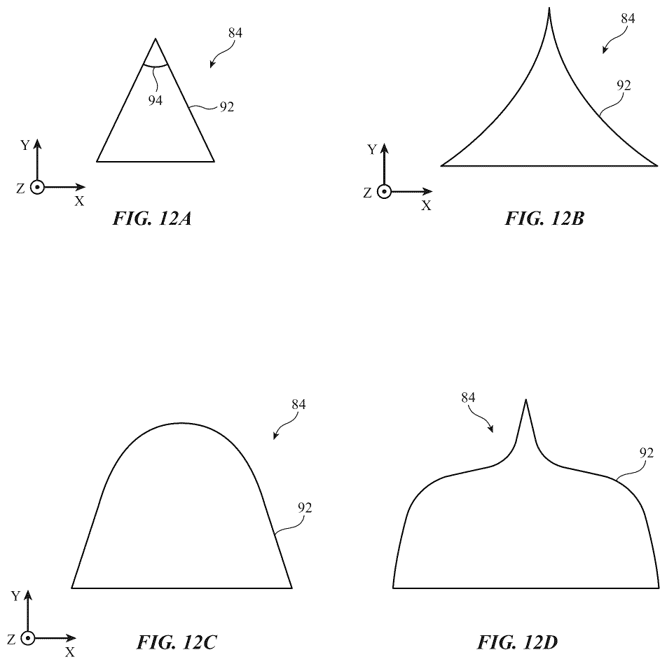

The protrusions may have any desired shape. FIGS. 12A-12C are top views of protrusions showing different possible footprints for the protrusions. In FIG. 12A, protrusion 84 is defined by linear sides 92 that meet at an angle 94. Angle 94 may be greater than 5 degrees, greater than 25 degrees, greater than 45 degrees, greater than 75 degrees, less than 85 degrees, less than 65 degrees, less than 45 degrees, less than 25 degrees, between 30 degrees and 60 degrees, etc. FIG. 12B shows an example where sides 92 of protrusion 84 have concave curvature. FIG. 12C shows an example where sides 92 of protrusion 84 have convex curvature. FIG. 12D shows an example where sides 92 of protrusion 84 have multiple curves (e.g., portions with convex curvature and portions with concave curvature).

Within a given subpixel, each protrusion may have the same shape (as in FIG. 11) or different protrusions may have different shapes.

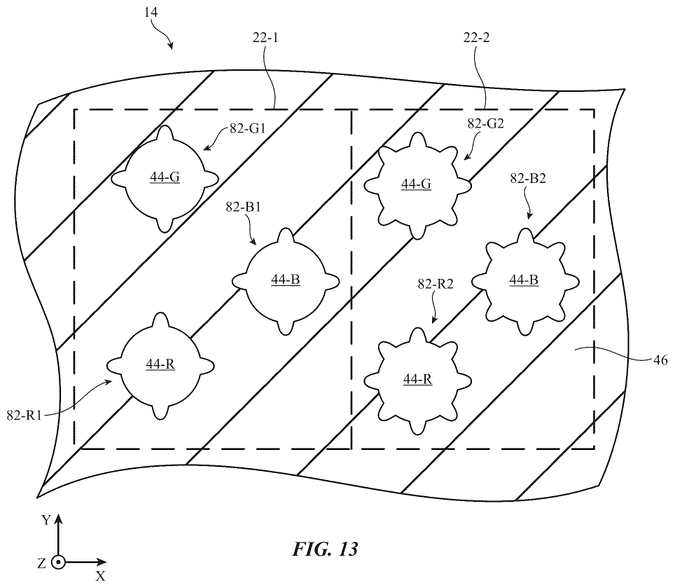

Additional mitigation of diffraction artifacts may be achieved by varying the footprint of subpixels between different pixels. FIG. 13 is a top view of a display with different pixels having different subpixel footprints. A first pixel 22-1 includes a first green subpixel 82-G1, a first blue subpixel 82-B1, and a first red subpixel 82-R1. A second pixel 22-2 includes a second green subpixel 82-G2, a second blue subpixel 82-B2, and a second red subpixel 82-R2.

As shown in FIG. 13, subpixel 82-G1 has a footprint with four protrusions whereas subpixel 82-G2 has a footprint with eight protrusions. The green subpixels in pixels 22-1 and 22-2 therefore have different, unique footprints. Subpixel 82-B1 has a footprint with four protrusions whereas subpixel 82-B2 has a footprint with eight protrusions. The blue subpixels in pixels 22-1 and 22-2 therefore have different, unique footprints. Subpixel 82-R1 has a footprint with four protrusions whereas subpixel 82-R2 has a footprint with eight protrusions. The red subpixels in pixels 22-1 and 22-2 therefore have different, unique footprints.

In general, increasing the number of unique footprints for subpixels of a given color may decrease diffraction artifacts in display 14. Display 14 may have green subpixels with at least 2 different unique footprints, at least 4 different unique footprints, at least 8 different unique footprints, at least 16 different unique footprints, at least 32 different unique footprints, etc. Display 14 may have red subpixels with at least 2 different unique footprints, at least 4 different unique footprints, at least 8 different unique footprints, at least 16 different unique footprints, at least 32 different unique footprints, etc. Display 14 may have blue subpixels with at least 2 different unique footprints, at least 4 different unique footprints, at least 8 different unique footprints, at least 16 different unique footprints, at least 32 different unique footprints, etc.

In general, subpixels with unique footprints may have protrusions of different shapes, protrusions of different heights, protrusions of different widths, protrusions of different pitches, a different number of protrusions, etc.

The protrusions of FIGS. 11-13 have been described in connection with a circular base shape for the subpixels. In other words, the protrusions originate at a circular footprint. Instead or in addition, one or more subpixels may have an elliptical footprint. When the subpixel has an elliptical footprint, the footprint may optionally include protrusions of the type shown in connection with FIGS. 11-13.

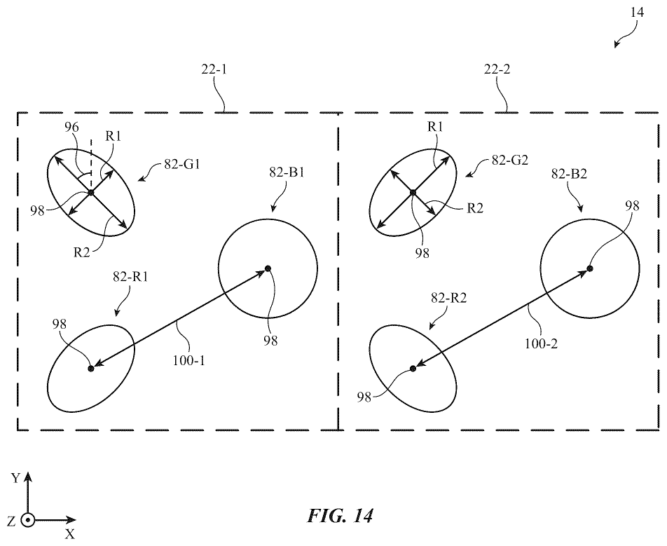

FIG. 14 is a top view of a display with different pixels having different subpixel footprints. A first pixel 22-1 includes a first green subpixel 82-G1, a first blue subpixel 82-B1, and a first red subpixel 82-R1. A second pixel 22-2 includes a second green subpixel 82-G2, a second blue subpixel 82-B2, and a second red subpixel 82-R2. Each subpixel has a respective center 98.

As shown in FIG. 14, subpixel 82-G1 has first elliptical footprint whereas subpixel 82-G2 has a second, different elliptical footprint. The green subpixels in pixels 22-1 and 22-2 therefore have different, unique elliptical footprints. Subpixel 82-B1 has first elliptical footprint whereas subpixel 82-B2 has a second, different elliptical footprint. The blue subpixels in pixels 22-1 and 22-2 therefore have different, unique elliptical footprints. Subpixel 82-R1 has first elliptical footprint whereas subpixel 82-R2 has a second, different elliptical footprint. The red subpixels in pixels 22-1 and 22-2 therefore have different, unique elliptical footprints.

Each elliptical footprint in FIG. 14 may be characterized by a first radius R1 through center 98, a second radius R2 through center 98, and a rotation angle 96. Radius R1 and radius R2 characterize the size and shape of the ellipse. Rotation angle 96 characterizes the rotation of the ellipse relative to a reference direction such as the Y-axis. Radius R1, radius R2, and rotation angle 96 may be different for subpixel 82-G2 than for subpixel 82-G1. Additionally, the relative position of the center of the subpixel may be different for subpixel 82-G1 than for subpixel 82-G2. In other words, the position of the center of the subpixel within the XY-plane may be adjusted between different pixels. This may cause the center-to-center pitch between subpixels of different colors to vary between pixels. For example, the separation 100-1 between the centers of subpixels 82-B1 and 82-R1 in pixel 22-1 may be different than the separation 100-2 between the centers of subpixels 82-B2 and 82-R2 in pixel 22-2.

In general, any properties associated with the elliptical footprint may be changed between pixels to increase randomization within the display and mitigate diffraction artifacts. For example, the green subpixels may have at least 2 unique elliptical shapes (e.g., R1 and R2 magnitudes) across the display, at least 4 unique elliptical shapes across the display, at least 8 unique elliptical shapes across the display, at least 16 unique elliptical shapes across the display, at least 32 unique elliptical shapes across the display, etc. Instead or in addition, the green subpixels may have at least 2 unique angles of rotation (e.g., magnitude of angle 96) across the display, at least 4 unique angles of rotation across the display, at least 8 unique angles of rotation across the display, at least 16 unique angles of rotation across the display, at least 32 unique angles of rotation across the display, etc. Instead or in addition, the green subpixels may have at least 2 unique relative center positions across the display, at least 4 unique relative center positions across the display, at least 8 unique relative center positions across the display, at least 16 unique relative center positions across the display, at least 32 unique relative center positions across the display, etc. The relative center positions may be measured as x and y coordinates of the center of a subpixel relative to a boundary of the pixel that includes that subpixel (e.g., the dashed lines in FIG. 14).

The red subpixels may have at least 2 unique elliptical shapes (e.g., R1 and R2 magnitudes) across the display, at least 4 unique elliptical shapes across the display, at least 8 unique elliptical shapes across the display, at least 16 unique elliptical shapes across the display, at least 32 unique elliptical shapes across the display, etc. Instead or in addition, the red subpixels may have at least 2 unique angles of rotation (e.g., magnitude of angle 96) across the display, at least 4 unique angles of rotation across the display, at least 8 unique angles of rotation across the display, at least 16 unique angles of rotation across the display, at least 32 unique angles of rotation across the display, etc. Instead or in addition, the red subpixels may have at least 2 unique relative center positions across the display, at least 4 unique relative center positions across the display, at least 8 unique relative center positions across the display, at least 16 unique relative center positions across the display, at least 32 unique relative center positions across the display, etc. The relative center positions may be measured as x and y coordinates of the center of a subpixel relative to a boundary of the pixel that includes that subpixel (e.g., the dashed lines in FIG. 14).

The blue subpixels may have at least 2 unique elliptical shapes (e.g., R1 and R2 magnitudes) across the display, at least 4 unique elliptical shapes across the display, at least 8 unique elliptical shapes across the display, at least 16 unique elliptical shapes across the display, at least 32 unique elliptical shapes across the display, etc. Instead or in addition, the blue subpixels may have at least 2 unique angles of rotation (e.g., magnitude of angle 96) across the display, at least 4 unique angles of rotation across the display, at least 8 unique angles of rotation across the display, at least 16 unique angles of rotation across the display, at least 32 unique angles of rotation across the display, etc. Instead or in addition, the blue subpixels may have at least 2 unique relative center positions across the display, at least 4 unique relative center positions across the display, at least 8 unique relative center positions across the display, at least 16 unique relative center positions across the display, at least 32 unique relative center positions across the display, etc. The relative center positions may be measured as x and y coordinates of the center of a subpixel relative to a boundary of the pixel that includes that subpixel (e.g., the dashed lines in FIG. 14).

Randomizing one or more properties in the pixels across the display may be referred to as dithering. As one option, global dithering may be performed where one or more properties (e.g., footprint shapes, sizes, rotations, etc.) are randomized for each pixel in the display. Alternatively, to reduce the cost and complexity of manufacturing display 14, the display may have a repeating unit cell of pixels with dithered pixels. Consider an example where a unit cell has 36 pixels in a 6×6 square. The 36 pixels in the unit cell may be dithered to mitigate refractive artifacts. The unit cell with the 36 dithered pixels may be repeated across the entire array of pixels for display 14.

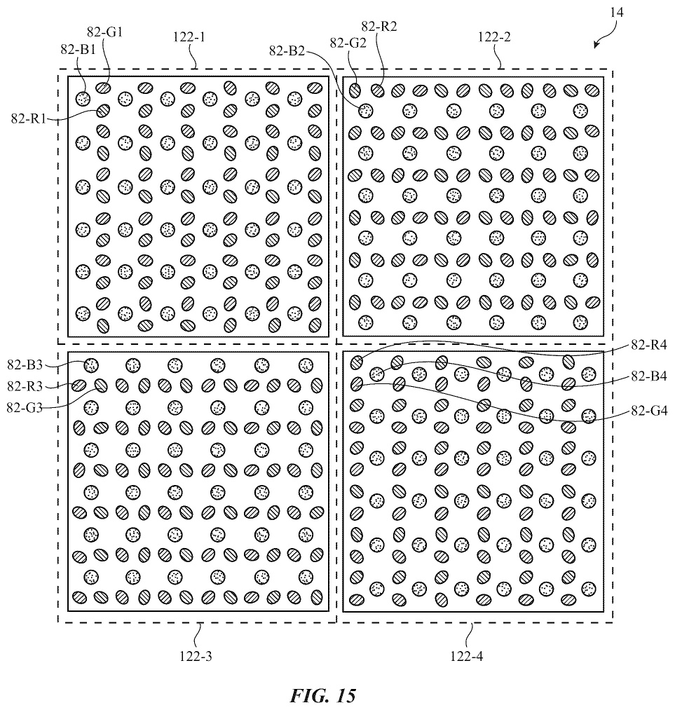

FIG. 15 is a top view of an illustrative display with a repeating unit cell of dithered pixels. As shown in FIG. 15, the display includes a plurality of unit cells 122 that are repeated across the display. Each display includes pixels. Each pixel includes a blue subpixel 82-B, a green subpixel 82-G, and a red subpixel 82-R. As shown in FIG. 15, the shapes and/or rotation of the subpixels may be randomized (dithered) across the unit cell.

In some cases, a single unit cell (e.g., unit cell 122-1) may be repeated across the display without further changes or randomization. Alternatively, the unit cell may be rotated to mitigate periodicity while leveraging the pattern of a single unit cell. FIG. 15 shows an example where the unit cells are arranged in 2×2 groups, with each unit cell in the 2×2 group rotated by 90 degrees relative to the preceding unit cell. In unit cell 122-1 in FIG. 15, each pixel has a blue subpixel 82-B1 on the left side of the pixel, a green subpixel 82-G1 on the upper right side of the pixel, and red subpixel 82-R1 on the lower right side of the pixel. The unit cell 122-2 in FIG. 15 is rotated by 90 degrees counterclockwise relative to unit cell 122-1 in FIG. 15. In unit cell 122-2, each pixel has a blue subpixel 82-B2 on the lower side of the pixel, a green subpixel 82-G2 on the upper left side of the pixel, and red subpixel 82-R2 on the upper right side of the pixel. The unit cell 122-3 in FIG. 15 is rotated by 90 degrees clockwise relative to unit cell 122-1 in FIG. 15. In unit cell 122-3, each pixel has a blue subpixel 82-B3 on the upper side of the pixel, a green subpixel 82-G3 on the lower right side of the pixel, and red subpixel 82-R3 on the lower left side of the pixel. The unit cell 122-4 in FIG. 15 is rotated by 90 degrees clockwise relative to unit cell 122-3 in FIG. 15. In unit cell 122-4, each pixel has a blue subpixel 82-B4 on the right side of the pixel, a green subpixel 82-G4 on the lower left side of the pixel, and red subpixel 82-R4 on the upper left side of the pixel.

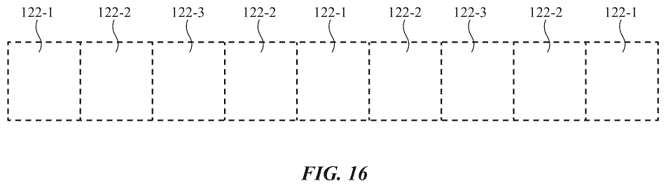

The example in FIG. 15 of including a group of unit cells that have the same layout rotated relative to one another is merely illustrative. In another possible arrangement, shown in FIG. 16, display 14 may include a plurality of repeating unit cells having unique subpixel layouts. In the example of FIG. 16, display 14 includes a first unit cell 122-1 having a first dithered layout of subpixels, a second unit cell 122-2 having a second dithered layout of subpixels that is different than the first layout, and a third unit cell 122-3 having a third dithered layout of subpixels that is different than the first and second layouts. In other words, the layouts of unit cells 122-1, 122-2, and 122-3 cannot simply be rotated to match one another as in FIG. 15. As shown in FIG. 16, the unit cells 122-1, 122-2, and 122-3 may be distributed randomly throughout display 14 to mitigate periodicity.

It is noted that the discussions of varying shapes herein (e.g., subpixel shapes) may include dithering the shapes of color filters for the subpixels, dithering the shapes of anodes for the subpixels, and/or dithering the shapes of black matrix openings for the subpixels. These components may be dithered together (e.g., the color filter, anode, and black matrix opening for a given subpixel may have the same shape) or independently (e.g., the color filter, anode, and black matrix opening for a given subpixel may different shapes).

Additionally, the subpixel shapes shown herein are merely illustrative. In general, any desired color filter, black matrix opening, and/or anode may have a circular shape, elliptical shape, polygonal shape, egg shape, one or more protrusions on any of the previously mentioned shapes, etc. In general, any desired color filter, black matrix opening, and/or anode may have asymmetric shapes.

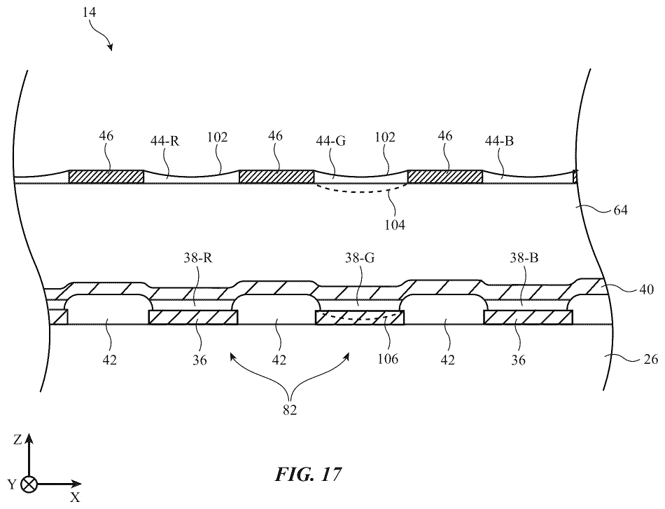

FIG. 17 is a side view of an illustrative display with color filter elements having concave curvature to mitigate diffraction artifacts. As shown, each color filter element 44 may have an upper surface 102 with concave curvature. Surface 102 may sometimes be referred to as concave upper surface 102. The concave curvature of the upper surface may cause the reflection profile associated with a given pixel to have gradual changes between the minimum and maximum reflectance magnitudes (as in FIG. 5B).

One or more additional components and/or surfaces may optionally have curvature instead of or in addition to the upper surface of color filter element 44. FIG. 17 shows how the lower surface 104 of color filter element 44 may optionally have convex curvature. Surface 104 may sometimes be referred to as convex lower surface 104. Similar to as with concave upper surface 102, convex lower surface 104 may cause the reflection profile associated with a given pixel to have gradual changes between the minimum and maximum reflectance magnitudes (as in FIG. 5B). FIG. 17 also shows how anode 36 may optionally have a concave upper surface 106. The concave upper surface of anode 36 may cause the reflection profile associated with a given pixel to have gradual changes between the minimum and maximum reflectance magnitudes (as in FIG. 5B). Cathode 40 may optionally have a curved portion over the curved anode if desired.

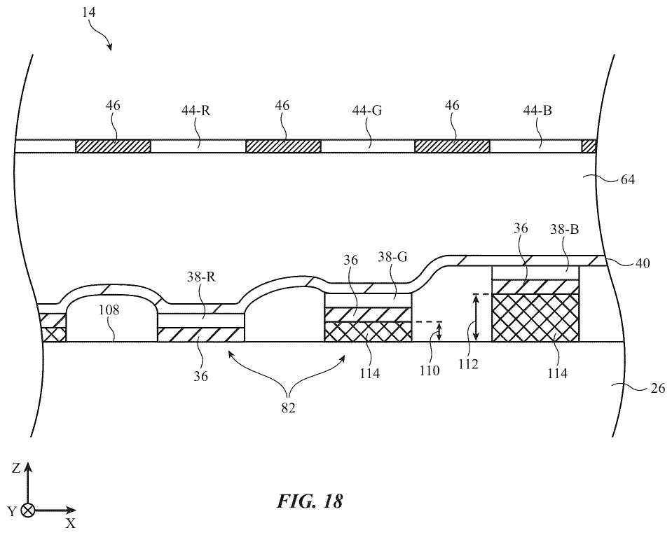

FIG. 18 is a side view of a display with anodes at varied heights to mitigate diffraction artifacts. As shown in 16, anodes 36 may be displaced by varying amounts relative to a surface 108 (sometimes referred to as upper surface 108) of substrate 26. Anode 36 for the red subpixel in FIG. 18 is positioned on upper surface 108 (e.g., with a displacement of 0 relative to the upper surface). Anode 36 for the green subpixel 82 is displaced by a distance 110 relative to upper surface 108. Anode 36 for the blue subpixel 82 is displaced by a distance 112 relative to upper surface 108. The magnitude of displacement in the Z-direction for the anodes may vary in different pixels to weaken periodic diffraction strength.

The green subpixels in the display may have at least 2 unique anode displacements relative to upper surface 108, at least 4 unique anode displacements relative to upper surface 108, at least 8 unique anode displacements relative to upper surface 108, at least 16 unique anode displacements relative to upper surface 108, at least 32 unique anode displacements relative to upper surface 108, etc. The red subpixels in the display may have at least 2 unique anode displacements relative to upper surface 108, at least 4 unique anode displacements relative to upper surface 108, at least 8 unique anode displacements relative to upper surface 108, at least 16 unique anode displacements relative to upper surface 108, at least 32 unique anode displacements relative to upper surface 108, etc. The blue subpixels in the display may have at least 2 unique anode displacements relative to upper surface 108, at least 4 unique anode displacements relative to upper surface 108, at least 8 unique anode displacements relative to upper surface 108, at least 16 unique anode displacements relative to upper surface 108, at least 32 unique anode displacements relative to upper surface 108, etc.

As shown in FIG. 18, the different unique anode displacements relative to upper surface 108 may be achieved using a spacer layer 114. The spacer layer 114 may be a dielectric material that displaces anode 36 relative to surface 108 of substrate 26. If desired, spacer layer 114 may be formed from the same material as substrate 26. Alternatively, spacer layer 114 may be formed from a different material as substrate 26. If desired, a trench in substrate 26 may be formed to cause a displacement between surface 108 and the anode for a given subpixel (e.g., a displacement in the negative Z-direction instead of in the positive Z-direction as in FIG. 18).

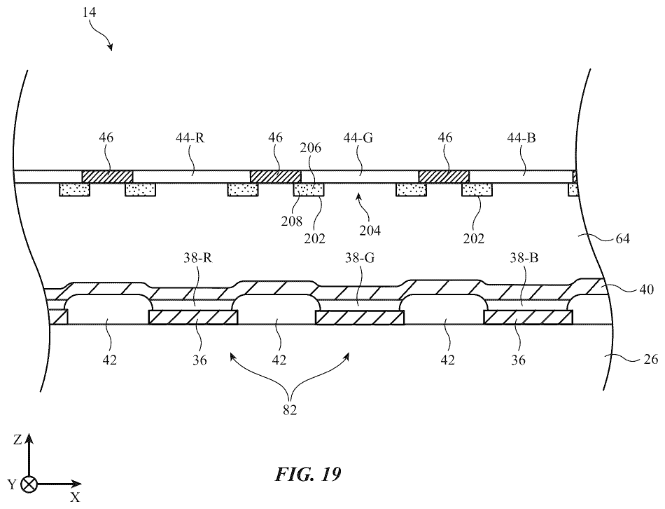

In another possible arrangement, one or more pixels may have a ring-shaped diffuser to mitigate diffraction artifacts. FIG. 19 is a side view of an illustrative display with ring-shaped diffusers. As shown in FIG. 19, each pixel may be overlapped by a corresponding ring-shaped diffuser 202 (sometimes referred to as diffuser 202, diffuser ring 202, etc.). Each ring-shaped diffuser 202 for a given pixel has a corresponding central opening that overlaps, in the Z-direction, a color filter associated with that pixel. A first portion of the ring-shaped diffuser ring (e.g., an innermost portion) may overlap, in the Z-direction, a light-emitting aperture of the given pixel defined by pixel definition layer 42. A second portion of the ring-shaped diffuser ring (e.g., an outermost portion) may overlap, in the Z-direction, a non-light-emitting portion of the given pixel. The second portion of the ring-shaped diffuser ring may overlap, in the Z-direction, pixel definition layer 42 between adjacent pixels.

Ring-shaped diffuser 202 may include diffusing particles 206 (sometimes referred to as light scattering particles or scattering particles) in a host material 208. The host material 208 may be transparent (e.g., with a transparency greater than 80%, greater than 90%, greater than 95%, etc.). The host material of diffusers 202 may be formed from a separate material than the adjacent planarization layer(s) 64. Alternatively, the host material of diffusers 202 may be formed from the same material as the adjacent planarization layer(s) 64. In this case, the scattering particles 206 may be considered to be embedded directly in planarization layer(s) 64.

With the arrangement of FIG. 19, the diffuser rings 202 cover the edge of the light-emitting apertures for each pixel, thereby providing the pixels with gradual boundaries that mitigate high order diffraction artifacts. Furthermore, the efficiency of the display is improved by omitting diffuser 202 over the center of the light-emitting aperture for each pixel.

A single display may optionally have one or more diffraction mitigating techniques described herein (e.g., the tapered surfaces of FIG. 6, the tapered surfaces of FIG. 7, the tapered surfaces of FIG. 8, the footprint with protrusions of FIG. 11, the elliptical footprints of FIG. 14, the varying footprints of FIGS. 13 and 14, one or more curved surfaces as in FIG. 17, repeating unit cells as in FIG. 15 or 16, varying anode heights as in FIG. 18, and/or ring-shaped diffusers as in FIG. 19).

The foregoing is merely illustrative and various modifications can be made by those skilled in the art without departing from the scope and spirit of the described embodiments. The foregoing embodiments may be implemented individually or in any combination.

What is claimed is:

1. A display comprising:
a substrate;
an array of light-emitting diodes on the substrate;
a black matrix that is formed over the array of light-emitting diodes and that defines a plurality of openings; and
a plurality of color filter elements, wherein each one of the plurality of color filer elements is formed in a respective opening of the plurality of openings and wherein at least one of the black matrix and the plurality of color filter elements has tapered surfaces to mitigate diffraction artifacts.

2. The display defined in claim 1, wherein the black matrix has the tapered surfaces to mitigate diffraction artifacts.

3. The display defined in claim 2, wherein a thickness of the black matrix changes as a function of position to define the tapered surfaces.

4. The display defined in claim 2, wherein the tapered surfaces are planar.

5. The display defined in claim 2, wherein the tapered surfaces have convex curvature.

6. The display defined in claim 2, wherein the tapered surfaces have concave curvature.

7. The display defined in claim 1, wherein the plurality of color filter elements has the tapered surfaces to mitigate diffraction artifacts.

8. The display defined in claim 7, wherein a thickness of a given color filter element changes as a function of position to define one of the tapered surfaces.

9. The display defined in claim 7, wherein the tapered surfaces are planar.

10. The display defined in claim 7, wherein the tapered surfaces have convex curvature.

11. The display defined in claim 7, wherein the tapered surfaces have concave curvature.

12. The display defined in claim 7, wherein a blue color filtering material is interposed between the black matrix and a green color filter element.

13. The display defined in claim 1, further comprising:
an opaque pixel definition layer that defines light-emitting apertures for the array of light-emitting diodes, wherein the opaque pixel definition layer has additional tapered surfaces.

14. The display defined in claim 13, wherein the additional tapered surfaces have concave curvature.

15. A display comprising:
a substrate;
an array of light-emitting diodes on the substrate;
a black matrix that defines openings for the light-emitting diodes; and
a plurality of color filter elements, wherein each one of the plurality of color filer elements is formed in a respective opening of the openings and wherein the openings have at least four unique footprints.

16. The display defined in claim 15, wherein each footprint in the at least four unique footprints comprises protrusions, wherein a property varies between each footprint in the at least four unique footprints, and wherein the property comprises a property selected from the group consisting of: a number of the protrusions, a shape of the protrusions, and a spacing of the protrusions.

17. The display defined in claim 15, wherein the at least four unique footprints comprise at least four unique elliptical footprints of different sizes.

18. A display comprising:
a substrate;
an array of light-emitting diodes on the substrate;
a black matrix that is formed over the array of light-emitting diodes and that defines a plurality of openings; and
a plurality of color filter elements, wherein each one of the plurality of color filer elements is formed in a respective opening of the plurality of openings and has a concave upper surface.

19. The display defined in claim 18, wherein each one of the plurality of color filer elements has a convex lower surface.

20. The display defined in claim 18, wherein each light-emitting diode in the array of light-emitting diodes comprises an anode with a concave upper surface.

21. A display comprising:
a substrate having a surface;
an array of light-emitting diodes on the substrate, wherein each light-emitting diode comprises an anode, wherein each anode has a displacement relative to the surface, and wherein there are at least four unique displacements in the array of light-emitting diodes;
a black matrix that is formed over the array of light-emitting diodes and that defines a plurality of openings; and
a plurality of color filter elements, wherein each one of the plurality of color filer elements is formed in a respective opening of the plurality of openings.

22. A display comprising:
a substrate;
an array of light-emitting diodes on the substrate;
a pixel definition layer that defines light-emitting apertures for the array of light-emitting diodes;
a plurality of ring-shaped diffusers that overlap the array of light-emitting diodes, wherein each ring-shaped diffuser in the plurality of ring-shaped diffusers overlaps an edge of a respective light-emitting aperture of a respective light-emitting diode in the array of light-emitting diodes;
a black matrix that is formed over the array of light-emitting diodes and that defines a plurality of openings; and
a plurality of color filter elements, wherein each one of the plurality of color filer elements is formed in a respective opening of the plurality of openings.
